(19) United States
(12) Patent Application Publication
(10) Pub. No.: US 2019/0200461 A1
(43) Pub. Date: Jun. 27, 2019

(54) HEAT-RESISTANT POWER MODULE SUBSTRATE, HEAT-RESISTANT PLATING FILM AND PLATING SOLUTION

(71) Applicant: C. Uyemura & Co., Ltd., Osaka (JP)

(72) Inventors: Siego Kurosaka, Osaka (JP); Yukinori Oda, Osaka (JP)

(21) Appl. No.: 16/175,672

(22) Filed: Oct. 30, 2018

(30) Foreign Application Priority Data
Dec. 22, 2017 (JP) 2017-246931

(51) Int. Cl. H05K 3/34; B23K 1/20; C23C 18/34

(52) U.S. Cl. CPC H05K 3/341; C23C 18/34; B23K 1/20

(57) ABSTRACT

The purpose of the present invention is to provide a heat-resistant power module substrate, a heat-resistant plating film, and plating solution capable of preventing occurrence of crack in a plating film, even if TCT with high temperature side set to 200□ or higher is performed. A heat-resistant power module substrate for mounting a power semiconductor generating high heat until maximum 300□, at least comprising: a base material composed of aluminum oxide, aluminum nitride or silicon nitride; a circuit composed of copper or aluminum and formed on the base material directly or via brazing material; and a plating film formed on a surface of the circuit, wherein the plating film is an electroless nickel-phosphorus-molybdenum plating film, and phosphorus content in the plating film is 10.5% to 13% by weight.

### BACKGROUND OF THE INVENTION

### Field of the Invention

The present invention relates to a heat-resistant power module substrate for mounting power semiconductor generating high heat, a heat-resistant plating film, and plating solution. The present application claims priority based on Japanese Patent Application No. 2017-246931 filed in Japan on Dec. 22, 2017, which is incorporated by reference herein.

### Description of Related Art

In the past, in a power module substrate, Si semiconductor chip is used frequently, and according to performance assurance of semiconductor chip, it was used in a condition that highest operating temperature is about 150□.

For the purpose of improving corrosion resistance of conductor circuit, in the power module substrate, nickel-phosphorus plating or the like capable of bearing the operating temperature was applied.

For example, in Patent Literature 1, an electroless nickel-phosphorus plating film targeting conventionally used resin substrate, ceramic substrate or the like, and having at least one component selected from iron, tungsten, molybdenum and chromium, applied at solder joint portion in a conductor circuit, in order to achieve high solder joint strength, is disclosed.

In addition, in Patent Literature 2, a method for plating an object to be plated, such as ceramic or aluminum, by electroless nickel-boron capable of obtaining high hardness without high temperature treatment, is disclosed.

Patent Literature 1: JP 2002-256444 A

Patent Literature 2: JP 3146065 B

### SUMMARY OF THE INVENTION

Generally, a power module is composed of a power semiconductor, a power module substrate (insulating substrate) and a cooler. The power semiconductor is having high heat quantity at the time of operation as it controls high voltage or high current. Conventionally, current voltage is controlled to control temperature rise of the power semiconductor itself, and also, heat dissipation is promoted by the cooler and the power module substrate mounting the power semiconductor, and it was controlled such that operating temperature of the power semiconductor will not be risen. On the other hand, a semiconductor chip of next generation such as SiC or GaN is having high heat resistance, and operation of the chip itself is possible, even if heat generation to the extent of maximum 300□ occurs in an instant. Therefore, conventional cooling ability is not necessary for entire module, and it is possible to downsize the cooler and else, so downsizing of entire module can be expected. On the other hand, bonding material such as solder exists between the power module substrate and the power semiconductor, but heat resistance higher than conventional heat resistance is required also for the power module substrate. In many cases, nickel-phosphorus plating is applied to a surface of wiring of the power module substrate, for the purpose of improving corrosion resistance and bonding reliability. In conventional nickel-phosphorus plating, there was a problem that crack occurs in a plating film, when low temperature side is set to −50□ and when high temperature side is set to 200□ or higher in temperature cycle test (hereinafter referred to as TCT), which is an evaluation test of heat resistance.

Here, the purpose of the present invention is to provide a heat-resistant power module substrate, a heat-resistant plating film, and plating solution for preventing occurrence of crack in the plating film, even if TCT is performed at the above temperatures.

A heat-resistant power module substrate relating to one embodiment of the present invention is the heat-resistant power module substrate for mounting a power semiconductor generating high heat until maximum 300□, at least comprising: a base material composed of aluminum oxide, aluminum nitride or silicon nitride; a circuit composed of copper or aluminum and formed on the base material directly or via brazing material; and a plating film formed on a surface of the circuit, wherein the plating film is an electroless nickel-phosphorus-molybdenum plating film, and phosphorus content in the plating film is 10.5% to 13% by weight.

In this way, it is possible to provide the heat-resistant power module substrate capable of preventing occurrence of crack in the plating film, even if TCT with high temperature side set to 200□ or higher is performed.

At this time, in one embodiment of the present invention, molybdenum content in the plating film may be 0.01% to 2.0% by weight.

In this way, it is possible to prevent occurrence of crack in the plating film even more.

In addition, in one embodiment of the present invention, phosphorus content in the plating film may be 11% to 13% by weight.

In this way, it is possible to prevent occurrence of crack in the plating film even more.

In addition, other embodiment of the present invention is a heat-resistant plating film to be formed on a surface of a circuit of a power module substrate for mounting a power semiconductor generating high heat until maximum 300□, wherein molybdenum content in the plating film is 0.01% to 2.0% by weight, phosphorus content in the plating film is 10.5% to 13% by weight, and the plating film is electroless nickel-phosphorus-molybdenum.

In this way, it is possible to provide the heat-resistant plating film capable of preventing occurrence of crack in the plating film, even if TCT with high temperature side set to 200□ or higher is performed.

In addition, in one embodiment of the present invention, phosphorus content in the plating film may be 11% to 13% by weight.

In this way, it is possible to prevent occurrence of crack in the plating film even more.

In addition, other embodiment of the present invention is electroless nickel-phosphorus-molybdenum plating solution for forming a heat-resistant plating film on a surface of a circuit of a power module substrate for mounting a power semiconductor generating high heat until maximum 300□, at least containing: nickel salt; complexing agent thereof; hypophosphite as reducing agent; and molybdate, wherein concentration of hypophosphite is 12 to 37 g/L as H₂PO₂ ion, and concentration of molybdate is 0.004 to 0.8 g/L as Mo ion.

In this way, it is possible to provide the plating solution capable of preventing occurrence of crack in the plating film, even if TCT with high temperature side set to 200□ or higher is performed.

As explained in the above, according to the present invention, it is possible to provide the heat-resistant power module substrate, the heat-resistant plating film, and the plating solution capable of preventing occurrence of crack in the plating film, even if TCT with high temperature side set to 200□ or higher is performed.

### BRIEF DESCRIPTION OF THE DRAWINGS

FIG. 1 is a sectional view illustrating a schematic structure of a heat-resistant power module substrate relating to one embodiment of the present invention.

### DETAILED DESCRIPTION OF THE INVENTION

Hereinafter, explaining in detail about preferred embodiments of the present invention. In addition, the embodiments explained in below will not unjustly limit the content of the present invention described in claims, and it is not limited that all the structures explained in the embodiments are necessary as means for solving the problem of the present invention. Explaining about a heat-resistant power module substrate, a heat-resistant plating film, and plating solution relating to one embodiment of the present invention in the following order.

1. Heat-resistant power module substrate

1-1. Base material

1-2. Circuit

2. Heat-resistant plating film
3. Plating solution

### [1. Heat-Resistant Power Module Substrate]

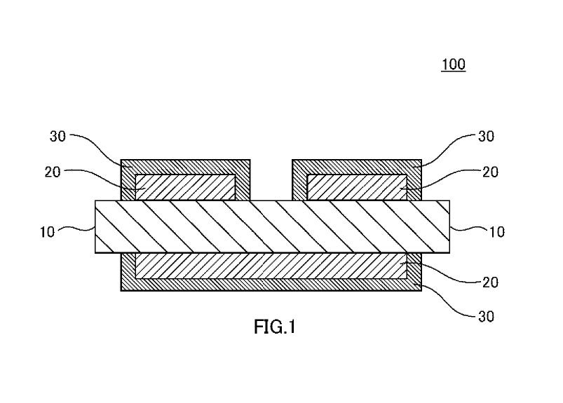

A heat-resistant power module substrate 100 relating to one embodiment of the present invention is a substrate for mounting a power semiconductor generating high heat until maximum 300□. And, as illustrated in FIG. 1, the heat-resistant power module substrate 100 relating to one embodiment of the present invention comprises: a base material 10 composed of aluminum oxide, aluminum nitride or silicon nitride; a circuit 20 composed of copper or aluminum and formed on the base material directly or via brazing material; and a plating film 30 formed on a surface of the circuit. It is explained in detail in below.

### [1-1. Base Material]

The base material 10 used for the heat-resistant power module substrate 100 relating to one embodiment of the present invention is composed of aluminum oxide, aluminum nitride or silicon nitride

In addition, the base material 10 used for the heat-resistant power module substrate 100 relating to one embodiment of the present invention is composed of aluminum oxide, aluminum nitride or silicon nitride, so it is excellent in cost, heat dissipation, strength and else compared to other ceramic materials.

### [1-2. Circuit]

Next, as illustrated in FIG. 1, the circuit 20 is formed on the base material 10. At this time, the circuit 20 may be formed on the base material 10 by direct process, or the circuit 20 may be formed on the base material 10 via brazing material (not illustrated). The circuit 20 is composed of copper or aluminum.

As forming process of the circuit 20, publicly known process may be used, and it is not limited particularly, but in direct process, oxidation treatment is performed to one surface of copper plate, which is a circuit member, and it is bonded with the base material 10, and etching may be performed to unnecessary portion other than the circuit. Aluminum is excellent in ductility, and copper is excellent in heat dissipation. In addition, these metals are also excellent in cost compared to other metals, so they are used for the power module substrate.

And, it is explained in detail about the plating film 30 formed on a surface of the circuit 20 in below.

### [2. Heat-Resistant Plating Film]

The plating film 30 formed on a surface of the circuit 20 of the heat-resistant power module substrate relating to one embodiment of the present invention is an electroless nickel-phosphorus-molybdenum plating film, wherein phosphorus content in the plating film is 10.5% to 13% by weight. In addition, it is explained later about plating solution used for the electroless nickel-phosphorus-molybdenum plating film.

As mentioned above, a semiconductor chip of next generation such as SiC, GaN is having high heat resistance, and it is possible to operate in 200□ or higher. At the same time, similar heat resistance is required also for a power module substrate, but in conventional nickel-phosphorus plating, there was a defect that crack occurs in a plating film, when low temperature side is set to −50□ and when high temperature side is set to 200□ or higher in TCT, which is evaluation test of heat resistance.

Further, conventionally, in electroless nickel-phosphorus plating, there is a film containing iron, tungsten, chromium or the like in the film by using the above metals instead of molybdenum. However, even by containing conventional metal such as iron, tungsten, or chromium, there is no effect for inhibiting occurrence of crack in the power module substrate against TCT with high temperature side set to 200□ or higher.

Here, the plating film 30 formed on the power module substrate relating to one embodiment of the present invention is capable of inhibiting occurrence of crack, even for TCT with high temperature side set to 200□ or higher. And, the plating film 30 is an electroless nickel-phosphorus-molybdenum plating film, and phosphorus content in the plating film is 10.5% to 13% by weight.

If phosphorus content in the plating film 30 is less than 10.5% by weight, when TCT is performed at the above temperatures, crack occurs in the plating film. On the other hand, if phosphorus content in the plating film 30 is more than 13% by weight, productivity will be decreased.

Further, it is preferable that phosphorus content in the plating film 30 is 11% to 13% by weight. In this way, it is possible to prevent occurrence of crack even more.

In addition, it is preferable that molybdenum content in the plating film 30 is 0.01% to 2.0% by weight. More preferably, molybdenum content is 0.2% to 2.0% by weight.

If molybdenum content in the plating film 30 is less than 0.01% by weight, when TCT is performed at the above temperatures, there is a possibility that crack occurs in the plating film. On the other hand, if molybdenum content in the plating film 30 is more than 2.0% by weight, molybdenum concentration in plating solution will be extremely high, so there is a possibility that productivity will be decreased as plating deposition rate decreases. Further, there is a possibility that there will be bare spot.

In addition, the heat-resistant plating film relating to one embodiment of the present invention is a film to be formed on a surface of the circuit of the power module substrate for mounting the power semiconductor generating high heat until maximum 300□, and molybdenum content and phosphorus content in the plating film is in the above range, and the plating film is electroless nickel-phosphorus-molybdenum.

As mentioned above, according to the heat-resistant power module substrate and the heat-resistant plating film relating to one embodiment of the present invention, it is possible to prevent occurrence of crack in the plating film, even if TCT with high temperature side set to 200□ or higher is performed. In below, it is explained about plating solution for forming the heat-resistant plating film of electroless nickel-phosphorus-molybdenum.

### [3. Plating Solution]

The plating solution relating to one embodiment of the present invention is plating solution for forming the heat-resistant plating film on a surface of the circuit of the power module substrate for mounting the power semiconductor generating high heat until maximum 300□, and it is electroless nickel-phosphorus-molybdenum plating solution.

Here, plating solution is solution to be used for plating, and it is solution that various metals and additives are condensed in one container, it is solution that various metals and additives are divided into a plurality of containers and that various metals and additives are condensed in each container, it is solution that the above condensed solution or the like is adjusted by water to prepare initial make-up of electrolytic bath, and it is solution that various metals and additives are added to adjust the solution to prepare initial make-up of electrolytic bath.

The plating solution relating to one embodiment of the present invention contains at least nickel salt, complexing agent thereof, hypophosphite as reducing agent, and molybdate, wherein concentration of hypophosphite is 12 to 37 g/L as H₂PO₂ ion, and concentration of molybdate is 0.004 to 0.8 g/L as Mo ion.

If concentration of hypophosphite, which is the reducing agent, is less than 12 g/L as H₂PO₂ ion, phosphorus content in the plating film will not be high, and when TCT is performed, crack occurs in the plating film. On the other hand, if concentration of hypophosphite is more than 37 g/L as H₂PO₂ ion, the plating solution will be unstable and the plating solution will be decomposed, or plating deposition rate will be slow and productivity will be decreased. In addition, preferred concentration of hypophosphite is 18 to 37 g/L as H₂PO₂ ion. As a process for adjusting phosphorus content in the plating film, for example when increasing phosphorus content, it can be increased by increasing concentration of hypophosphite in the plating solution, or by decreasing pH of the plating solution. When decreasing phosphorus content, reverse operation is performed.

In addition, if concentration of molybdate is less than 0.004 g/L as Mo ion, molybdenum content in the plating film will not be high, and when TCT is performed, crack occurs in the plating film. On the other hand, if concentration of molybdate is more than 0.8 g/L as Mo ion, plating deposition rate will be slow and productivity will be decreased. In addition, preferred concentration of molybdate is 0.04 to 0.8 g/L as Mo ion. As a process for adjusting molybdenum content in the plating film, for example when increasing molybdenum content, it can be increased by increasing concentration of molybdate in the plating solution. When decreasing molybdenum content, reverse operation is performed.

Thus, concentration of H₂PO₂ ion of hypophosphite and Mo ion of molybdate used for the plating solution relating to one embodiment of the present invention is in the above range, and in this way, it is possible to prevent occurrence of crack in the plating film.

Hypophosphite as reducing agent used for the plating solution relating to one embodiment of the present invention is not limited, but sodium hypophosphite, potassium hypophosphite, nickel hypophosphite or the like may be used.

Molybdate used for the plating solution relating to one embodiment of the present invention is not limited, but sodium molybdate, potassium molybdate, ammonium molybdate, or the like may be used.

Nickel salt used for the plating solution relating to one embodiment of the present invention is not limited, but for example, inorganic water-soluble nickel salt such as nickel sulfate, nickel chloride and nickel hypophosphite, and organic water-soluble nickel salt such as nickel acetate and nickel malate may be used. In addition, these water-soluble nickel salts can be used solely, or by mixing more than two kinds of nickel salts.

In addition, concentration of nickel ion in the plating solution is, for example preferably 2 to 8 g/L as metal nickel, and more preferably 4 to 6 g/L. If nickel concentration is too low, plating rate may be slow, so it is not preferable. In addition, if nickel concentration is too high, the plating solution may become clouded, or viscosity of the plating solution may become high, so uniformity of deposition may be decreased, and pit may be occurred in the formed plating film, so it is not preferable.

Complexing agent used for the plating solution relating to one embodiment of the present invention is not limited, but various complexing agents used in publicly known electroless nickel plating solution may be used. As concrete examples of the complexing agent: amino acid such as glycine, alanine, arginine, aspartic acid, glutamic acid, lysine or phenyl alanine; monocarboxylic acid such as lactic acid, propionic acid, glycolic acid or gluconic acid; dicarboxylic acid such as tartaric acid, oxalic acid, succinic acid or malic acid; and tricarboxylic acid such as citric acid, may be cited. In addition, salts thereof, for example sodium salt or potassium salt can be used as complexing agent. In addition, these complexing agents may be used solely, or by mixing more than two kinds of complexing agents.

In addition, concentration of complexing agent in the plating solution differs by types of complexing agent to be used, but it is preferably 10 to 200 g/L, more preferably 30 to 100 g/L. If concentration of complexing agent is too low, precipitation of nickel hydroxide tends to occur, so it is not preferable. In addition, if concentration of complexing agent is too high, viscosity of the plating solution will become high, so uniformity of deposition may be decreased, and it is not preferable.

Further, mass ratio of concentration of the nickel salt, complexing agent thereof, H₂PO₂ ion of hypophosphite and Mo ion of molybdate is preferably 1:1.25 to 100:1.5 to 18.5:0.0005 to 0.4. In this way, it will be appropriate ratio of concentration, and it is possible to prevent occurrence of crack in the plating film.

In addition, in the plating solution relating to one embodiment of the present invention, the molybdenum is added as additive metal other than nickel, but iron, tungsten, chromium and tin will not be contained instead of molybdenum, and iron, tungsten, chromium and tin will not be contained in addition to molybdenum.

Additionally, publicly known stabilizing agent and reducing agent may be used. In addition, pH is 3 to 7, preferably 4 to 6. Plating time may be adjusted to be target thickness of the film.

As mentioned above, according to the plating solution relating to one embodiment of the present invention, it is possible to prevent occurrence of crack in the plating film, even if TCT with high temperature side set to 200□ or higher is performed.

### EXAMPLES

Next, explaining in detail about the heat-resistant power module substrate, the heat-resistant plating film and the plating solution relating to one embodiment of the present invention, by using examples. In addition, the present invention is not limited to these examples.

### Example 1

In example 1, as a base material to be used in a heat-resistant power module substrate, DAB substrate (ceramics: aluminum nitride 50 mm*50 mm-0.8 mm (thickness), aluminum: 40 mm*40 mm-0.6 mm (thickness)*2 (both sides), total thickness: 2.0 mm (thickness)) was used. In addition, a copper circuit was formed directly on the base material. And, an electroless nickel-phosphorus-molybdenum plating film formed by following conditions was applied on the circuit.

As composition of the electroless nickel-phosphorus-molybdenum plating solution, nickel sulfate (II) hexahydrate was 27.0 g/L, in other words, nickel ion was 6 g/L, sodium hypophosphite was 30 g/L (18.4 g/L as H₂PO₂ ion), lead acetate (II) trihydrate was 1 mg/L, sodium molybdate was 0.1 g/L (0.040 g/L as Mo ion), malic acid was 20 g/L, succinic acid was 15 g/L, and sodium hydroxide was 5 g/L. In addition, plating time was 35 minutes, liquid temperature was 90□, and pH was 4.5.

In addition, composition was analyzed after forming the plating film. More concretely, the electroless plating film after plating deposition was dissolved in nitric acid, and this solution was performed of quantitative analysis of phosphorus and molybdenum, or tungsten or tin by ICP (made by HORIBA, product name: Ultima Expert), and from weight of dissolved plating film, mass % of each component in the plating film was calculated.

And, crack inhibition effect of the plating film formed by the above plating process was evaluated, by performing temperature cycle test (TCT) using a small cold impact testing device (made by ESPEC CORP., product name: TSE-11), for confirmation of crack inhibition effect. More concretely, after leaving the plating film in a condition of high temperature: 200□ for 40 minutes, it was left in a condition of low temperature: −50□ for 20 minutes, and this was one cycle. This cold impact was repeated until occurrence of crack in the plating film. It was evaluated until maximum 1000 cycles. Occurrence of crack was confirmed by using optical microscope.

### Example 2

In example 2, sodium molybdate was 0.5 g/L (0.198 g/L as Mo ion). Other conditions were same as the example 1.

### Example 3

In example 3, sodium molybdate was 1.0 g/L (0.397 g/L as Mo ion). Other conditions were same as the example 1.

### Example 4

In example 4, sodium molybdate was 0.5 g/L (0.198 g/L as Mo ion). In addition, plating time was 25 minutes, and pH was 4.8. Other conditions were same as the example 1.

### Example 5

In example 5, sodium molybdate was 0.5 g/L (0.198 g/L as Mo ion), malic acid was 40 g/L, and succinic acid was 30 g/L. In addition, plating time was 60 minutes, and pH was 4.4. Other conditions were same as the example 1.

### Example 6

In example 6, sodium molybdate was 0.01 g/L (0.004 g/L as Mo ion). Other conditions were same as the example 1.

### Comparative Example 1

In comparative example 1, sodium molybdate was not added. Other conditions were same as the example 1.

### Comparative Example 2

In comparative example 2, sodium molybdate was 5 g/L (1.983 g/L as Mo ion). Other conditions were same as the example 1.

### Comparative Example 3

In comparative example 3, sodium molybdate was 0.5 g/L (0.198 g/L as Mo ion), and sodium hypophosphite was 15 g/L (9.2 g/L as H₂PO₂ ion). In addition, plating time was 60 minutes, and pH was 4.6. Other conditions were same as the example 1.

### Comparative Example 4

In comparative example 4, sodium molybdate was 0.05 g/L (0.020 g/L as Mo ion), and sodium hypophosphite was 15 g/L (9.2 g/L as H₂PO₂ ion). In addition, glycine was added instead of malic acid and succinic acid, which are complexing agent, and glycine was 12 g/L. Further, pH was 6.2. Other conditions were same as the example 1.

### Comparative Example 5

In comparative example 5, sodium tungstate was added instead of adding sodium molybdate, and sodium tungstate was 20 g/L. Other conditions were same as the example 1.

### Comparative Example 6

In comparative example 6, tin methane sulfonate was added instead of adding sodium molybdate, and tin methane sulfonate was 0.3 g/L. Other conditions were same as the example 1.

The above conditions were indicated in table 1. In addition, concentration of sodium molybdate and sodium hypophosphite were respectively indicated by Mo ion and H₂PO₂ ion in table 1. In addition, content of the film obtained in the conditions of table 1 and result of cycle number of crack occurrence were indicated in table 2. In addition, cycle number indicated in table 2 indicates cycle number at which crack was occurred in the plating film. In addition, >1000 indicates that crack was not occurred even after performing 1000 cycles of TCT.

TABLE 1

| | | Composition of plating solution | | | | | | |
|---|---|---|---|---|---|---|---|---|
| | | | | | | | | Comparative |
| | | Example 1 | Example 2 | Example 3 | Example 4 | Example 5 | Example 6 | example 1 |
| Nickel sulfate (II) | g/L | 27.0 | 27.0 | 27.0 | 27.0 | 27.0 | 27.0 | 27.0 |
| hexahydrate | | | | | | | | |
| Ni ion | g/L | 6 | 6 | 6 | 6 | 6 | 6 | 6 |
| H₂PO₂ ion of sodium | g/L | 18.4 | 18.4 | 18.4 | 18.4 | 18.4 | 18.4 | 18.4 |
| hypophosphite | | | | | | | | |
| Lead acetate (II) trihydrate | mg/L | 1 | 1 | 1 | 1 | 1 | 1 | 1 |
| Mo ion of sodium molybdate | g/L | 0.040 | 0.198 | 0.397 | 0.198 | 0.198 | 0.004 | 0 |
| Sodium tungstate | g/L | — | — | — | — | — | — | — |
| Tin methane sulfonate | g/L | — | — | — | — | — | — | — |
| Malic acid | g/L | 20 | 20 | 20 | 20 | 40 | 20 | 20 |
| Succinic acid | g/L | 15 | 15 | 15 | 15 | 30 | 15 | 15 |
| Glycine | g/L | — | — | — | — | — | — | — |
| Sodium hydroxide | g/L | 5 | 5 | 5 | 5 | 5 | 5 | 5 |
| Plating time | Min | 35 | 35 | 35 | 25 | 60 | 35 | 35 |
| Liquid temperature | ° C. | 90 | 90 | 90 | 90 | 90 | 90 | 90 |
| pH | — | 4.5 | 4.5 | 4.5 | 4.8 | 4.4 | 4.5 | 4.5 |

| | | Composition of plating solution | | | | |
|---|---|---|---|---|---|---|
| | | Comparative | Comparative | Comparative | Comparative | Comparative |
| | | example 2 | example 3 | example 4 | example 5 | example 6 |
| Nickel sulfate (II) | g/L | 27.0 | 27.0 | 27.0 | 27.0 | 27.0 |
| hexahydrate | | | | | | |
| Ni ion | g/L | 6 | 6 | 6 | 6 | 6 |
| H₂PO₂ ion of sodium | g/L | 18.4 | 9.2 | 9.2 | 18.4 | 18.4 |
| hypophosphite | | | | | | |
| Lead acetate (II) trihydrate | mg/L | 1 | 1 | 1 | 1 | 1 |
| Mo ion of sodium molybdate | g/L | 1.983 | 0.198 | 0.020 | — | — |
| Sodium tungstate | g/L | — | — | — | 20 | — |
| Tin methane sulfonate | g/L | — | — | — | — | 0.3 |
| Malic acid | g/L | 20 | 20 | — | 20 | 20 |
| Succinic acid | g/L | 15 | 15 | — | 15 | 15 |
| Glycine | g/L | — | — | 12 | — | — |
| Sodium hydroxide | g/L | 5 | 5 | 2 | 5 | 5 |
| Plating time | Min | 35 | 60 | 35 | 35 | 35 |
| Liquid temperature | ° C. | 90 | 90 | 90 | 90 | 90 |
| pH | — | 4.5 | 4.6 | 6.2 | 4.5 | 4.5 |

TABLE 2

| | | | Conditions of plating film | | | | | | | | | | | |
|---|---|---|---|---|---|---|---|---|---|---|---|---|---|---|
| | | | | | | | | | Compar- | Compar- | Compar- | Compar- | Compar- | Compar- |
| | | | Exam- | Exam- | Exam- | Exam- | Exam- | Exam- | ative | ative | ative | ative | ative | ative |
| | | | ple 1 | ple 2 | ple 3 | ple 4 | ple 5 | ple 6 | example 1 | example 2 | example 3 | example 4 | example 5 | example 6 |
| Content | P | wt. % | 11.5 | 11.5 | 11.4 | 10.5 | 13.0 | 11.5 | 11.6 | Cannot | 9.0 | 2.3 | 11.2 | 11.1 |
| of film | Mo | wt. % | 0.2 | 1.0 | 2.0 | 1.0 | 1.0 | 0.02 | — | be plated | 0.7 | 0.2 | — | — |
| | W | wt. % | — | — | — | — | — | — | — | | — | — | 1.5 | — |
| | Sn | wt. % | — | — | — | — | — | — | — | | — | — | — | 5.0 |

| | | | | | | | | | | | | |
|---|---|---|---|---|---|---|---|---|---|---|---|---|
| Cycle number of | >1000 | >1000 | >1000 | 900 | >1000 | 900 | 500 | — | 400 | 300 | 400 | 400 |
| crack occurrence | | | | | | | | | | | | |

In all examples, crack did not occur in the plating film when less than 900 cycles of TCT were performed. Thus, it can be understood that the plating film excellent in crack inhibition effect by improvement of heat resistance had been formed. In addition, in the examples 1, 2, 3 and 5, in which concentration of phosphorus in the plating film was 11% to 13% by weight, and also, molybdenum content was 0.2% to 2.0% by weight, crack did not occur in the plating film, even after more than 1000 cycles of TCT were performed. Thus, the plating film in the above concentration range was more effective against crack.

On the other hand, in the comparative examples, crack occurred in the plating film when 300 to 500 cycles of TCT were performed. In addition, in the comparative example 2, plating was not formed as too much sodium molybdate were added in plating solution. Further, in the comparative example 1 in which sodium molybdate was not added, and in the comparative examples 5 and 6 in which sodium tungstate or tin methane sulfonate were added instead of sodium molybdate, crack occurred in the plating film when 400 to 500 cycles of TCT were performed.

From the above, according to the heat-resistant power module substrate, the heat-resistant plating film and the plating solution relating to one embodiment of the present invention, it was possible to prevent occurrence of crack in the plating film, even if TCT with high temperature side set to 200□ or higher was performed

In addition, it is explained in detail about each embodiment and each example of the present invention as the above, but it can be understood easily for those who skilled in the art that various modifications are possible without practically departing from new matters and effect of the present invention. Therefore, all of such variants should be included in the scope of the present invention.

For example, terms described with different terms having broader or equivalent meaning at least once in description and drawings can be replaced with these different terms in any part of description and drawings. In addition, operation and configuration of the heat-resistant power module substrate, the heat-resistant plating film and the plating solution are not limited to those explained in each embodiment and each example of the present invention, and various modifications can be made.

### GLOSSARY OF DRAWING REFERENCES

10 Base material
20 Circuit
30 Plating film
100 Heat-resistant power module substrate

1. A heat-resistant power module substrate for mounting a power semiconductor generating high heat until maximum 300□, at least comprising:
a base material composed of aluminum oxide, aluminum nitride or silicon nitride;
a circuit composed of copper or aluminum and formed on the base material directly or via brazing material; and
a plating film formed on a surface of the circuit,
wherein the plating film is an electroless nickel-phosphorus-molybdenum plating film, and phosphorus content in the plating film is 10.5% to 13% by weight.

2. The heat-resistant power module substrate according to claim 1, wherein molybdenum content in the plating film is 0.01% to 2.0% by weight.

3. The heat-resistant power module substrate according to claim 2, wherein phosphorus content in the plating film is 11% to 13% by weight.

4. A heat-resistant plating film to be formed on a surface of a circuit of a power module substrate for mounting a power semiconductor generating high heat until maximum 300□,
wherein molybdenum content in the plating film is 0.01% to 2.0% by weight, phosphorus content in the plating film is 10.5% to 13% by weight, and the plating film is electroless nickel-phosphorus-molybdenum.

5. The heat-resistant plating film according to claim 4, wherein phosphorus content in the plating film is 11% to 13% by weight.

6. Electroless nickel-phosphorus-molybdenum plating solution for forming a heat-resistant plating film on a surface of a circuit of a power module substrate for mounting a power semiconductor generating high heat until maximum 300□, at least containing:
nickel salt; complexing agent thereof; hypophosphite as reducing agent; and molybdate,
wherein concentration of hypophosphite is 12 to 37 g/L as H₂PO₂ ion, and concentration of molybdate is 0.004 to 0.8 g/L as Mo ion.
